(19) United States
(12) Patent Application Publication
(10) Pub. No.: US 2023/0268157 A1
(43) Pub. Date: Aug. 24, 2023

(54) SPECIMEN HOLDER

(71) Applicant: Mel-Build Corporation, Fukuoka (JP)

(72) Inventor: Hiroya Miyazaki, Fukuoka (JP)

(21) Appl. No.: 18/010,119

(22) PCT Filed: Jun. 23, 2021
(86) PCT No.: PCT/JP2021/023735

§ 371 Date: Dec. 13, 2022

(30) Foreign Application Priority Data
Jul. 3, 2020 (JP) 2020-115844

(51) Int. Cl. H01J 37/20

(52) U.S. Cl. CPC H01J 37/20; H01J 2237/2007; H01J 2237/2008; H01J 2237/20214; H01J 2237/002

(57) ABSTRACT

A specimen holder includes a specimen shaft unit having a specimen and/or specimen mesh setting unit; an outer tubular unit capable of housing the specimen holder shaft unit; a cooling unit; and a thermoelectric element placed close to the cooling unit. In certain examples, the thermoelectric element may use at least one effect selected from the Peltier effect and the Thomson effect.

### TECHNICAL FIELD

The present invention relates to a specimen holder and an electron microscope having the specimen holder; and more particularly to a specimen holder capable of cooling a specimen and an electron microscope having the specimen holder.

### BACKGROUND ART

In recent years, high-resolution analysis has progressed in electron microscopes such as transmission electron microscopes (TEMs) and scanning transmission electron microscopes (STEMs). For example, there is a demand for high-resolution analysis from nano-order to pico-order. In recent years, “in-situ observation”, which involves cooling (or heating, applying an electric field, applying a magnetic field, or rotating) while observing a specimen in an electron microscope, has been attracting attention. For example, most of the existing cooling holders use liquid nitrogen or liquid helium as a cooling medium (a coolant), and the mainstream method is to cool the specimen from the outside of the TEM housing through thermal conduction. In most cases, the cooling temperature is their boiling point (liquid nitrogen: about −196° C., liquid helium: about −269° C.). It is possible to control the temperature above the boiling point by installing a heater in the middle of the heat conduction path. However, heating above a certain level causes bubbling in the liquid nitrogen due to the heat of the heater, and the vibration significantly lowers the resolution of the microscope image, making it difficult to use. Therefore, with commercially available cooling holders, the temperature control range for stable operation and observation is generally about −269° C. to −100° C. From this point of view, there is known a specimen cooling device for an electron microscope that efficiently dissipates heat generated on the high temperature side of the Peltier element into the atmosphere and improves the cooling efficiency (Patent literature 1).

### PRIOR ART LITERATURE

### Patent Literature

Patent literature 1 JP 6-260125 A

### SUMMARY OF INVENTION

### Problems to be Resolved by the Invention

However, in the prior art including Patent literature 1, since the Peltier type cooling holders mainly have a structure in which the heat absorbing surface of the Peltier element and the heat conducting path are fixed, it is difficult to arrange a rotation axis for biaxial tilting. Further, in the Peltier type cooling, it is necessary to cool the heat of the heat radiating surface of the Peltier element using the atmosphere (air) or running water. Either natural convection or forced convection may be used, but in the case of natural convection, if the heat dissipation side is covered with a cover, etc., heat dissipation will be insufficient, so the heat dissipation side must be exposed to the atmosphere as much as possible. Also, in order to obtain sufficient heat absorption, forced convection such as running water is desirable, but in the case of forced convection, depending on the device, convection or pulsating current causes the microscopic image to sway, resulting in a significant reduction in resolution.

Therefore, in order to solve the above problems, the present invention is to provide a specimen holder that can rotate the specimen while cooling it.

### Means of Solving the Problems

In order to achieve the above object, the present inventors have made intensive studies on the cooling mechanism of the specimen holder, and as a result, have found the present invention.

That is, the specimen holder of the present invention is characterized in that a specimen holder comprises:
a specimen shaft unit having a specimen and or specimen mesh setting unit;
an outer tubular unit capable of housing the specimen holder shaft unit;
a cooling unit; and
a thermoelectric element placed close to the cooling unit.

Further, in a preferred embodiment of the specimen holder of the present invention, it is characterized in that the thermoelectric element is a thermoelectric element that utilizes at least one effect selected from the Peltier effect and the Thomson effect.

Further, in a preferred embodiment of the specimen holder of the present invention, it is characterized in that the heat radiation side of the thermoelectric element and the cooling unit are in contact with each other.

Further, in a preferred embodiment of the specimen holder of the present invention, it is characterized in that a cooling medium of the cooling unit is composed of a solid cooling medium, a liquid cooling medium, or a gas cooling medium.

Further, in a preferred embodiment of the specimen holder of the present invention, it is characterized in that the heat from the thermoelectric element is transferred to the specimen holder shaft unit.

Further, in a preferred embodiment of the specimen holder of the present invention, it is characterized in that the heat is transferred via a clamping mechanism.

Further, in a preferred embodiment of the specimen holder of the present invention, it is characterized in that the specimen holder shaft unit is rotatable.

Further, in a preferred embodiment of the specimen holder of the present invention, it is characterized in that the specimen holder shaft unit is movable back and forth.

Further, in a preferred embodiment of the specimen holder of the present invention, it is characterized in that the cooling unit is detachable.

Further, in a preferred embodiment of the specimen holder of the present invention, it is characterized in that the specimen holder main body and the cooling unit have an attachment connecting unit for switching cooling medium that connects the specimen holder main body and the cooling unit.

Further, in a preferred embodiment of the specimen holder of the present invention, it is characterized in that the cooling medium is a solid cooling medium, a liquid cooling medium, or a gas cooling medium.

### Effect of Invention

According to the specimen holder of the present invention, there is an advantageous effect that cooling and rotation can be performed while observing the specimen.

According to the specimen holder of the present invention, there is an advantageous effect, that the cooling/heating response is excellent and the influence of thermal drift can be suppressed as much as possible. Moreover, according to the specimen holder of the present invention, the cooling/heating response is improved, so there is an advantageous effect that precise temperature control is possible.

In addition, according to the specimen holder of the present invention, since it has a thermoelectric element such as a Peltier, it is possible to observe for a long time under cooling, and as a result, there is an advantageous effect that EDS analysis and EELS analysis can be performed for a long time.

### BRIEF DESCRIPTION OF THE DRAWINGS

FIG. 1 shows a specimen holder in one embodiment of the invention. FIG. 1(a) shows a top view of a specimen holder in one embodiment of the present invention. 1(b) shows a cross-sectional view taken along line B-B of FIG. 1(a), and FIG. 1(c) shows a cross-sectional view taken along line A-A of FIG. 1(a).

FIG. 2 shows one embodiment of a thermoelectric element applicable to the present invention. FIG. 2(a) shows a cross-sectional view of a Peltier element, and FIG. 2(h) shows a schematic diagram of the principle of the Peltier element.

FIG. 3 shows a specimen holder in one embodiment of the invention.

### MODE FOR CARRYING OUT THE INVENTION

The specimen holder of the present invention is characterized in that a specimen holder comprises:
a specimen shaft unit having a specimen and/or specimen mesh setting unit;
an outer tubular unit capable of housing the specimen holder shaft unit;
a cooling unit; and
a thermoelectric element placed close to the cooling unit. The specimen holder shaft unit having the specimen and/or the specimen mesh mounting portion is not particularly limited, and may have only the specimen mounting portion for mounting the specimen.

In addition, in the present invention, the arrangement position of the cooling unit (section) is not particularly limited, but for example, it can be arranged on the handle side of the specimen holder. Specifically in the cooling unit, liquid nitrogen, liquid helium, or a solid coolant can be used to cool the specimen holder shaft, the shielding unit (section (if present)), and the specimen.

In the present invention, a thermoelectric element is provided close to the cooling unit. In the present invention, the arrangement position of the thermoelectric element is not particularly limited as long as it is installed close to the cooling unit. A thermoelectric element makes it possible to set the required temperature of the specimen in an efficient manner, that is, to control the temperature.

In the present invention, the thermoelectric element may be arranged in the vicinity of the cooling unit. For example, a structure in which a cooling unit such as a solid cooling medium (a solid refrigerant) is pressed against the heat radiation surface side may be used, or a structure in which a gap is provided and cool air is applied with the gap may be used. When applying cool air, either natural convection or forced convection using a fan or the like may be used, but if forced convection causes vibration, natural convection is preferable, although it depends on the degree of forced convection. Even in the case of natural convection, since the solid cooling medium has a sufficiently low temperature, there is a large temperature gradient between the heat radiation surface side and the cold air in the cooling unit such as the solid cooling medium (refrigerant, coolant), so sufficient heat transfer occurs. Therefore, it is considered that the heat radiation surface can be cooled appropriately. Moreover, forced convection is more effective than natural convection, and water cooling is more effective than air cooling.

That is, in a preferred embodiment of the specimen holder of the present invention, it is characterized in that a cooling medium of the cooling unit is composed of a solid cooling medium, a liquid cooling medium, or a gas cooling medium. As described above and below, the cooling medium can be solid, liquid, or gaseous.

Furthermore, in a preferred embodiment of the specimen holder of the present invention, the thermoelectric element is a thermoelectric element that utilizes at least one effect of the Peltier effect and the Thomson effect. The Peltier effect (also known as the Peltier effect) is an effect that converts electrical energy into thermal energy, and is a phenomenon that occurs when two dissimilar metals (or semiconductors) are connected to each other and an electric current is passed through them, causing a temperature difference between the two ends. The Peltier effect is especially called a Peltier element, it is used for cooling precision instruments and wine cellars. In addition, the Thomson effect is the effect of generating heat other than Joule heat (heat absorption when reversing the current) that occurs when an electric current is passed through a uniform metal (or dissimilar metal) with a temperature gradient. Both effects can generate heat or absorb heat.

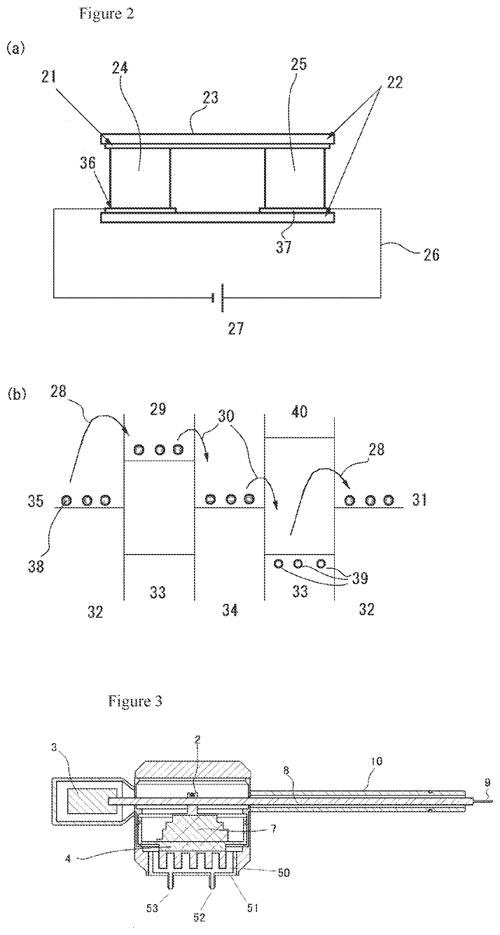

Further, in a preferred embodiment of the specimen holder of the present invention, the thermoelectric element is a Peltier element from the viewpoint of having good cooling/heating response and suppressing the influence of thermal drift as much as possible. A Peltier element is also called a Peltier element (thermo module), which is a general term for elements utilizing the Peltier effect. The currently mainstream structure, which is said to have the best performance, is called the “π-type”, and has the structure shown in FIG. 2. By passing a current through a PN junction portion using a P-type semiconductor and an N-type semiconductor, it is possible to cause heat dissipation between P-N and heat absorption between N-P.

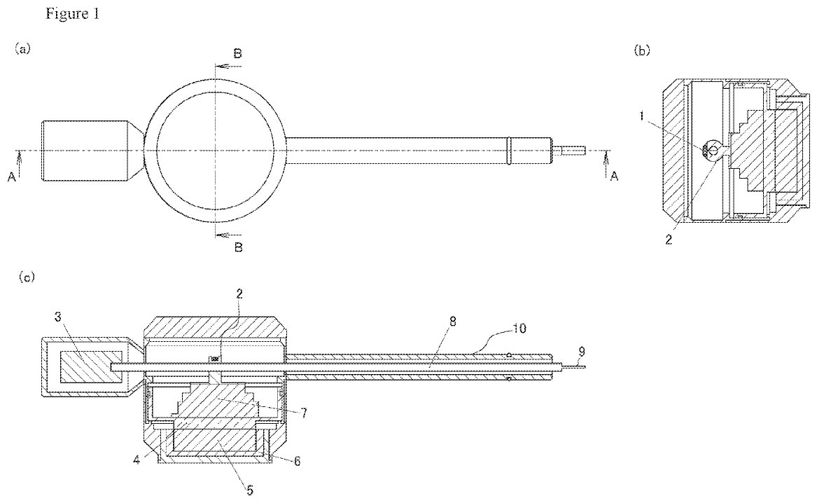

The principle is as follows. FIG. 2 shows one embodiment of a thermoelectric element applicable to the present invention. FIG. 2(a) shows a cross-sectional view of a Peltier element, and FIG. 1(b) shows a schematic diagram of the principle of the Peltier element. In FIG. 2(a), 21 is a metal on a hot side (mainly Cu), 22 is a ceramic substrate (mainly alumina), 23 is a heat dissipation surface, 24 is an N-type semiconductor, 25 is a P-type semiconductor, 26 is an electric wire, 27 is the power source, 28 is the heat absorption, 29 is the conduction band of the N-type semiconductor, 30 is the heat dissipation, 31 is the plus side, 32 is the heat absorption side, 33 is the valence band, 34 is the heat dissipation side, 35 is the minus side, 36 is a metal on a cold side (mainly Cu), 37 is a metal on a cold side (mainly Cu), 38 is an electron, 39 is a positive hole, and 40 is a conduction band of the P-type semiconductor, respectively.

In FIG. 2(a), the minus electrode is connected to the metal 36 on the side of the N-type semiconductor 24. Therefore, electrons are pushed up from the conduction band of this metal 36 to the conduction band 29 of the N-type semiconductor 24 by the voltage. At this time, since there is an energy gap between the conduction band of the metal 36 and the conduction band 29 of the N-type semiconductor 24, the electrons take heat energy from the metal 36 and as a result cool the metal 36. Electrons subsequently flow and fall from the conduction band 29 of the N-type semiconductor 24 into the conduction band of the metal 21. The electrons release thermal energy due to the energy gap between both bands. The metal 21 on the hot side is thus heated. Further, the electrons that have flowed fall from the conduction band of the metal 21 into the positive holes 39 that have flowed through the P-type semiconductor 25 and release thermal energy to heat the metal 21 on the hot side. In the P-type semiconductor 25, the positive holes 39 are produced by voltage and flow from the cold side 37 to the hot side 21. The electrons generated at that time are pushed up to the conduction band of the metal on the cold side by the voltage, deprive the heat energy corresponding to the energy gap between them, and cool the metal 37 on the cold side. This flow of current makes it possible to transfer heat from the cold side to the hot side of the Peltier module. In addition to heat energy carried by electric current, there is heat energy carried by heat conduction. However, since the heat energy carried by heat conduction flows in the opposite direction, the less heat energy carried by heat conduction, the better the performance of the Peltier module. In other words, the Peltier module will exhibit good performance if the heat energy on the hot side is removed as quickly as possible with a heat sink or the like. Simply put, electrons carry (take away) heat.

Although the material of the semiconductor is not particularly limited and any material can be used, Bi—Te semiconductors are considered to have the best performance and are the mainstream.

Regarding the performance of the Peltier, generally speaking, the performance of the Peltier can be considered by how much temperature difference ΔT can be created with respect to the temperature Th when the temperature on the heat radiation side is kept constant. For example, ΔT=93, 85, 75 for Th=75, 50, 25 (° C.). If the heat-dissipating surface (heat radiating surface) is simply cooled to the temperature of liquid nitrogen (−196° C.), it is thought that the temperature of the heat-absorbing surface will exceed −200° C. However, actually it is assumed that ΔT=10° C., near liquid nitrogen due to the characteristics of the material. The lower the temperature, the less heat is needed to excite electrons, so the Peltier cooling ability decreases. Therefore, it is thought that this is because the Peltier cooling capacity is reduced and the electric resistance of the semiconductor portion increases as the temperature decreases, and therefore, the cooling capacity as a whole decreases as a result of self-heat generation due to current.

Further, in a preferred embodiment of the specimen holder of the present invention, from the viewpoint that it is possible to set even lower temperatures by cooling the heat radiation side of the thermoelectric element, it is characterized in that the heat radiation side of the thermoelectric element and the cooling unit are in contact with each other. In the following examples, the case of cooling is mainly described, but in the present invention, it is also possible to heat with a thermoelectric element.

In the case of heating, the phenomenon is simply reversed compared to the case of cooling, but the practicality also changes depending on the shape (whether it is a multistage type or not) of the thermoelectric element such as a Peltier element. Basically, when aiming at an infinitely low temperature, a multi-stage thermoelectric element such as a Peltier element can be used. In this case, it is possible to form a pyramid-like structure in which the area of the heat absorption surface (upper stage) is small and the area becomes large toward the heat dissipation surface. The reason for such a structure is that, basically, the larger the area, the larger the amount of heat absorption, so that the heat absorbed by the upper element with a small area is discharged by the lower element with a larger area. When using for the purpose of heating by reversing the polarity of the current, it is not simple, and the heat from the lower stage, which has a large area, tends to flow into the upper stage, which has a small area, at once. If the upper stage cannot absorb the heat, the heat accumulates in the middle stage and tends to be higher than the upper stage. For this reason, many Peltier elements are considered to be around +110° C. (the temperature at which the solder at the junction portion does not deteriorate) even if they are used on the heating side.

Liquid nitrogen needs to be replenished when it runs out, but in the present invention, since it has a thermoelectric element such as a Peltier with a forced convection chiller, it is possible to observe it under cooling for a long time. Therefore, Long-term EDS analysis and EELS analysis are possible. Moreover, a forced convection chiller can mean, for example, a chiller that forcibly circulates a cooling medium on a heat radiation surface. For example, as a forced convection chiller, it is possible to apply a cooling medium with low pulsation and a low temperature of −20 degrees.

Further, in a preferred embodiment of the specimen holder of the present invention, from the viewpoint that vibration does not occur due to the low pulsation chiller, the balance of the center of gravity weight, and other complex factors, it is characterized in that a cooling medium of the cooling unit is composed of a solid cooling medium, a liquid cooling medium, or a gas cooling medium. That is, in the present invention, the heat radiating surface of the Peltier element or the like can be cooled with a solid cooling medium such as dry ice, a liquid cooling medium such as water, or a gaseous cooling medium such as various gases. This makes it possible to make the influence of vibrations infinitely zero. Moreover, as a supplementary explanation about the balance of the center of gravity, by designing the handle, that is, the heat dissipation surface (heat sink) of the Peltier to be heavy the heat sink can receive the vibration caused by the convection, and the vibration can be suppressed. Also, in the case of forced convection in a chiller or the like, since bubbles do not enter by making it a structure that does not create an air layer, it is possible to adapt to forced convection by suppressing vibration caused by bubbles.

On the other hand, even when the cooling gas is flowed at a normal flow rate including a very small flow rate, the effect of vibration is small, so these can be used in the present invention. As the cooling gas, for example, mention may be made of those taken out, by gasifying liquid nitrogen. In the present invention, the cooling gas is not limited to liquid nitrogen. If the gas is simply passed through the heat radiation surface, it is considered practical with almost no effect of vibration. Therefore, in the present invention, as described above, even when a solid cooling medium is actually used as the cooling unit, it is sufficient to apply cold air with a gap instead of pressing it against the heat dissipation surface. Furthermore, similarly, when liquid nitrogen gas is used, observation is possible without being affected by vibration by passing the cooling gas through the heat radiation surface.

Further, in a preferred embodiment of the specimen holder of the present invention, it is characterized in that the heat from the thermoelectric element is transferred to the specimen holder shaft. It is sufficient that the heat from the thermoelectric element can be transferred to the specimen holder shaft. For example, the heat from the thermoelectric element can be brought into contact with the specimen holder via a member. In a preferred embodiment, heat from the thermoelectric element can be transferred to the specimen holder shaft through a heat conducting unit. Due to the existence of such a heat conducting unit, if the thermoelectric element and the specimen holder shaft are connected by the heat conducting unit made of a heat conductive member, the heat from the cooling unit can be transferred to the specimen holder shaft and the specimen. Moreover, the heat conducting unit is not particularly limited as long as it can contact the specimen holder shaft so as not to damage the biaxial tilting mechanism of the specimen holder shaft.

In the present invention, the heat conducting unit is not particularly limited as long as it can conduct heat efficiently, and examples thereof include pure copper, copper alloys, and aluminum alloys or the like. In addition, copper mixed with (STC) carbon, or any material with good thermal conductivity that can be machined is acceptable.

Further, in a preferred embodiment of the specimen holder of the present invention, it is characterized in that the heat is transferred via a clamping mechanism. In the present invention, the heat conducting unit can preferably have a clamping mechanism. As a result, the biaxial tilting mechanism of the specimen is not disturbed and cooling is also possible with higher performance.

Further, in a preferred embodiment of the specimen holder of the present invention, it is characterized in that the specimen holder shaft unit is rotatable, in the present invention, the mechanism that allows the specimen holder shaft unit to rotate is not particularly limited in accordance with a conventional method. For example, in the present invention, by connecting the specimen holder shaft unit to a motor or the like and rotating the specimen holder shaft unit, it is possible, to interlock with the biaxial tilting mechanism of the tip, thereby making the specimen tiltable. Thus, the present invention can also be applied to a mode including a biaxial tilting mechanism for the specimen.

Further, in a preferred embodiment of the specimen holder of the present invention, it is characterized in that the specimen holder shaft unit is movable back and forth. In the present invention, the mechanism that allows the specimen holder shaft unit to move back and forth, that is, the mechanism that makes the specimen holder shaft unit movable between the center direction of the electron microscope and the so-called handle direction of the specimen holder, is not particularly limited according to a conventional method. According to such an aspect, the specimen holder of the present invention can correspond to the atmosphere non-exposure mechanism. For example, as a mode of moving back and forth, after connecting the holder handle (handle) unit and the specimen holder shaft unit, pulling the handle unit backward drives the specimen holder shaft unit in the axial direction, and the tip of the holder can be stored in the outer cylinder unit. By storing it in the outer cylinder unit, it becomes possible to separate the atmosphere from the inside of the holder.

Further, in a preferred embodiment of the specimen holder of the present invention, it is characterized in that the cooling unit is detachable. By making it detachable, it is possible to easily handle any cooling medium. By changing the cover of the heat radiation surface, it is possible to easily handle any type of the cooling medium. There are no particular restrictions on the method of making the device detachable, and a common method is used.

Further, in a preferred embodiment of the specimen holder of the present invention, it is characterized in that the specimen holder main body and the cooling unit have an attachment connecting unit for switching cooling medium that connects the specimen holder main body and the cooling unit. This also makes it possible to handle any cooling medium more simply. In other words, by replacing the cooling unit, it is possible to perform water cooling or forced convection of vaporized liquid nitrogen gas. The advantage of forced convection is that the heat-dissipating surface can be cooled continuously, and a device that is convenient for long-term observation and analysis can be provided. The connecting unit is not particularly limited as long as it, can connect the specimen holder main body and the cooling unit. As for the connection method, it is possible to use a conventional method.

As described above, since the forced convection of the cooling water does not cause vibration, even if the cooling medium is not a solid cooling medium, if it has a structure that does not cause vibration, it will not be affected by vibration even if the cooling water is forced to convect. If there is no vibration, forced convection by cooling water can be the most efficient and suitable for long-term observation. Cooling water is an example, and is not limited to water as long as it is forced convection. For example, Fluorinert and Galden can be used as representative examples of the refrigerant. Further, in a preferred embodiment of the specimen holder of the present invention, it is characterized in that the cooling medium can be a solid cooling medium, a liquid cooling medium, or a gas cooling medium even if the cooling part is detachable.

Next, an example specimen holder in one embodiment of the present invention will be described with reference to FIG. 1, but the present invention is not intended to be construed as being limited to the example below.

FIG. 1 shows a specimen holder in one embodiment of the invention. FIG. 1(a) shows a top view of a specimen holder in one embodiment of the present invention. 1(b) shows a cross-sectional view taken along line B-B of FIG. 1(a), and FIG. 1(c) shows a cross-sectional view taken along line A-A of FIG. 1(a). In FIG. 1, 1 is an elastic member, 2 is a heat conducting unit, 3 is a biaxial drive motor, 4 is a heat sink, 5 is a cooling unit, 6 is a heat insulating part (heat insulating material), 7 is a thermoelectric element (Peltier element), 8 is a specimen holder axis (biaxial tilt axis, heat conduction axis), 9 is a specimen and/or specimen mesh setting portion (unit), and 10 an outer cylindrical unit, respectively.

In FIG. 1(b), 2 is a heat conducting unit, which has a clamping mechanism in this example. 1 is an elastic member such as a spring, which can be appropriately adjusted so as not to hinder the rotation of the specimen holder shaft (biaxial tilt shaft, heat conduction shaft) 8 and to provide appropriate thermal contact.

In FIG. 1(c), 2 is a heat conducting unit, which has a clamping mechanism in this example. The clamping mechanism can be appropriately adjusted so as not to impede rotation of the specimen holder axis (biaxial tilt axis, heat transfer axis) 8 and to provide adequate thermal contact. 3 is a biaxial driving motor, which is required for observations requiring biaxial driving. 4 is a heat sink and 5 is a cooling unit. Specifically liquid nitrogen, liquid helium, solid cooling medium, or the like can be used in the cooling unit, and is not particularly limited. A solid cooling medium such as dry ice can be used as the cooling unit when observation with higher accuracy is required. Also, as described above, it is possible to use a cooling gas in the cooling unit. Even when cooling with a cooling gas (liquid nitrogen gas, etc.), observation with high resolution is possible without the influence of pulsation compared to water cooling. 6 is a heat insulating unit (part) (heat insulating material), and 7 is a thermoelectric element, which is a Peltier element in this example. By cooling the heat radiation side of the Peltier element (Peltier device) with air cooling or water cooling (refrigerant or cooling medium), it is possible to cool down to a lower temperature. Heat (cooling or heating) controlled by the Peltier element can be conducted to the specimen holder axis (biaxial tilt axis, heat transfer axis) 8 via the heat transfer unit 2. The heat transferred through the heat conducting unit can cool or heat the specimen and/or the specimen mesh mounting portion 9. In the present invention, in an embodiment using a solid cooling medium (dry ice, etc.; −78.5 degrees), vibration become almost zero compared to water-cooled. Peltier cooling, and stable observation with high resolution is possible. It was also found that the use of the heat conductive unit such as a thermally conductive clamp enables more stable observation by biaxial tilting. It was also found that using a solid cooling medium such as dry ice for the heat radiation surface of the Peltier element is suitable for a lower temperature range, for example, −100° C.

Also, FIG. 3 is a diagram showing a specimen holder in one embodiment of the present invention in another aspect. In FIG. 3, 2 is a heat conduction unit, 3 is a biaxial drive motor, 4 is a heat sink, 7 is a thermoelectric element (Peltier element), 8 is a specimen holder axis (biaxial tilt axis, heat conduction axis), 9 is a specimen and/or a specimen mesh setting portion, 10 is an outer cylindrical unit, 50 is a coolant heat sink attachment, 51 is a cover for the cooling medium or the forced cooling, 52 is a cooling medium OUT, and 53 is a cooling medium IN, respectively.

In FIG. 3, 2 is a heat conducting unit, which has a clamping mechanism in this example. The clamping mechanism can be appropriately adjusted so as not to impede rotation of the specimen holder axis (biaxial tilt axis, heat transfer axis) 8 and to provide adequate thermal contact. 3 is a biaxial driving motor; which is required for observations requiring biaxial driving. 4 is a heat sink, and the cooling unit is detachable in this embodiment. A solid cooling medium, a liquid cooling medium, or a gas cooling medium can be used as the cooling medium used for cooling. Specifically; liquid cooling mediums such as water, liquid nitrogen, and liquid helium, gaseous cooling mediums of various gases, solid cooling mediums, or the like can be used, and are not particularly limited. A thermoelectric element 7 is a Peltier element in this example. By cooling the heat radiation side of the Peltier device with air cooling or water cooling (cooling medium, or refrigerant), it is possible to cool down to a lower temperature. Heat (cooling or heating) controlled by the Peltier element can be conducted to the specimen holder axis (biaxial tilt axis, heat transfer axis) 8 via the heat transfer part 2. The heat transferred through the heat conducting unit can cool or heat the specimen and/or the specimen mesh mounting portion 9. Thus, in the present invention, by changing the cover of the heat radiating surface, it is possible to adapt to any cooling medium. It was found that it is also possible to perform water cooling or forced convection of vaporized liquid nitrogen gas, and the advantage of forced convection is that the heat radiation surface can be cooled continuously making it suitable for long-term observation and analysis. In the present invention, even forced convection by cooling water does not cause vibration, so it was found that even if the cooling water is not a solid refrigerant, if the structure does not cause vibration, even forced convection of cooling water will not be affected by vibration. It was also found that forced convection by cooling water is the most efficient and suitable for long-term observation when there is no vibration. Cooling water is an example, and is not limited to water as long as it is forced convection. Representative examples of refrigerants include Fluorinert and Galden.

In this way, according to the present invention, it was found that in order to create an intermediate temperature on the low temperature side (around −100 degrees to 0 degrees), the Peltier element is placed outside the housing (near the handle portion of the specimen holder) in the same way as a liquid nitrogen cooling type of the cooling holder, and it is possible to cool the tip of the specimen by heat conduction. In principle, the temperature of the Peltier element can be precisely controlled from near room temperature to the minus range by creating a heat absorption surface and a heat dissipation surface by the movement of electrons and controlling the amount, of current flowing through the Peltier element. Due to these effects, it was found that it is possible to manufacture a thermoelectric element type specimen holder that enables biaxial tilting and stable high-resolution observation, and depending on the cooling medium, stable observation for a long period of time.

### INDUSTRIAL APPLICABILITY

A specimen holder that can be cooled without interfering with biaxial tilting contributes to in-situ observation and is applicable in a wide range of technical fields.

### DESCRIPTION OF THE REFERENCE NUMERALS

1 an elastic member
2 a heat conducting unit
3 a biaxial drive motor
4 a heat sink
5 a cooling unit
6 a heat insulating unit (part) (heat insulating material)
7 a thermoelectric element (Peltier element)
8 a specimen holder axis (biaxial tilt axis, heat conduction axis)
9 a specimen and/or specimen mesh setting portion (unit)
10 an outer cylindrical unit
21 a metal on a hot side (mainly Cu)
22 a ceramic substrate (mainly alumina)
23 a heat dissipation surface
24 an N-type semiconductor
25 a T-type semiconductor
26 an electric wire
27 the power source
28 the heat absorption
29 the conduction band of the N-type semiconductor
30 the heat dissipation
31 the plus side
32 the heat absorption side
33 the valence band
34 the heat dissipation side
35 the minus side
36 a metal on a cold side (mainly Cu)
37 a metal on a cold side (mainly Cu)
38 an electron
39 a positive hole
40 a conduction band of the P-type semiconductor,
50 a coolant heat sink attachment
51 a cover for the cooling medium (coolant) or the forced cooling
52 a cooling medium OUT
53 a cooling medium IN

1. A specimen holder comprises:
a specimen shaft unit having a specimen and/or specimen mesh setting unit;
an outer tubular unit capable of housing the specimen holder shaft unit;
a cooling unit; and
a thermoelectric element placed close to the cooling unit.

2. A specimen holder according to claim 1, wherein the thermoelectric element is a thermoelectric element that utilizes at least one effect selected from the Peltier effect and the Thomson effect.

3. The specimen holder according to claim 1, wherein the heat radiation side of the thermoelectric element and the cooling unit are in contact with each other.

4. The specimen holder according to claim 1, characterized in that a cooling medium of the cooling unit is composed of a solid cooling medium, a liquid cooling medium, or a gas cooling medium.

5. The specimen holder according to claim 1, characterized in that the heat from the thermoelectric element is transferred to the specimen holder shaft unit.

6. The specimen holder according to claim 5, wherein the heat is transferred via a clamping mechanism.

7. The specimen holder according to claim 1, wherein the specimen holder shaft unit is rotatable.

8. The specimen holder according to claim 1, wherein the specimen holder shaft unit is movable back and forth.

9. The specimen holder according to claim 1, characterized in that the cooling unit is detachable.

10. The specimen holder according to claim 9, wherein the specimen holder main body and the cooling unit have an attachment connecting unit for switching cooling medium that connects the specimen holder main body and the cooling unit.

11. The specimen holder according to claim 10, characterized in that the cooling medium is a solid cooling medium, a liquid cooling medium, or a gas cooling medium.
